(19) United States
(12) Patent Application Publication
(10) Pub. No.: US 2019/0137560 A1
(43) Pub. Date: May 9, 2019

(54) BLOCK HEATER TEST SYSTEMS

(71) Applicants: Dan Kenneth Johnson, Camrose (CA); Jacki Johnson, Camrose (CA)

(72) Inventors: Dan Kenneth Johnson, Camrose (CA); Jacki Johnson, Camrose (CA)

(21) Appl. No.: 16/236,164

(22) Filed: Dec. 28, 2018

Related U.S. Application Data
(63) Continuation-in-part of application No. 15/047,390, filed on Feb. 18, 2016.

(51) Int. Cl. G01R 31/02; F02N 19/02; G01R 31/00

(52) U.S. Cl. CPC G01R 31/026; G01R 31/006; F02N 19/02

(57) ABSTRACT

A block heater test system for testing continuity in a vehicle's block heater. The block heater test system plugs into the power cord of a block heater to test continuity for the purpose of making sure the block heater can be powered. The block heater test system relies on a battery. So, no other power source is needed; but alternate power sources can be used. An indicator light or audible tone indicates a fault in the block heater or indicates correct operation of the heater depending on the design. The small nature of block heater test system and the weather resistant housing allow for easy use during inclement weather.

### CROSS-REFERENCE TO RELATED APPLICATION(S)

The present application is a Continuation in part of pending U.S. patent application Ser. No. 15/047,390 filed Feb. 18, 2016, which is incorporated by reference herein in its entirety.

### BACKGROUND OF THE INVENTION

The following includes information that may be useful in understanding the present invention(s). It is not an admission that any of the information provided herein is prior art, or material, to the presently described or claimed inventions, or that any publication or document that is specifically or implicitly referenced is prior art.

### FIELD OF THE INVENTION

The present invention relates generally to the field of automotive testing devices and more specifically relates to a block heater test system.

### DESCRIPTION OF RELATED ART

Many regions of the world experience extremely cold climates at certain times of the year. Engines are often equipped with block heaters in these regions. Many people in cold climate areas rely on block heaters to warm their vehicle's engine for the purpose of allowing a quicker start. These individuals use an electric heater element on the cylinder block connected with a power cord routed through the vehicle's grill. However, a convenient way to test the block heater before plugging it in to a power source may not be available for various reasons. In order to check if a block heater is functioning properly, a continuity check must be made. The equipment needed to successfully check continuity on a block heater may not be readily available. Being outside in extreme weather and not having access to or the knowledge to use a device for testing continuity can leave someone stranded in a potentially dangerous situation. Therefore, it is desirable to have a self-contained block heater tester that is easy to use and portable.

Several attempts have been made to solve the above-mentioned problems such as those found in U.S. Pat. No. 5,784,015 to Stewart R. Duffin et al.; U.S. Pat. No. 3,962,630 to Bertram Chaffee; and U.S. Pat. No. 4,249,125 to Clem Carver. International patents CA 2,149,997 to Michael J. Anka; and CA 2,007,630 to Michel Potvin. This art is representative of automotive testing devices. However, none of the above inventions and patents, taken either singly or in combination, is seen to describe the invention as claimed.

Preferably, an automotive block heater tester should provide a means to easily test the continuity of a vehicle's block heater in any weather condition and, yet would operate reliably and be manufactured at a modest expense. Thus, a need exists for a reliable block heater test system to avoid the above-mentioned problems.

### BRIEF SUMMARY OF THE INVENTION

In view of the foregoing disadvantages inherent in the known automotive testing devices art, the present invention provides a novel block heater tester system. The general purpose of the present invention, which will be described subsequently in greater detail is to provide a block heater tester that is useful for checking continuity in a block heater before connecting the block heater to a power source.

A tester is disclosed, which in some embodiments comprises a housing having a power adapter or an interior power source, an outer surface with a female outlet, an indicator light, and an optional activation switch inside of the interior of the housing. These components are wired together using a wiring harness. The housing can have a rear cover that includes an attachment aperture. In some embodiments, the tester has several states, such as, testing states that can have an energized configuration and a non-energized configuration and standby states that include an energized configuration and a non-energized configuration. In some variations, the testing state occurs when the block heater is connected to the tester outlet and the standby state occurs when the heater is not connected to the tester outlet. In an energized configuration, the circuit supplies a voltage across the outlet and in a non-energized state the circuit does not supply a voltage across the outlet.

In some embodiments, when the heater is functional, it has a continuous electrical path. When the activation switch is closed, the indicator light (sometimes a light emitting diode) illuminates. Sometimes the internal power source comprises a battery or a rechargeable battery. And in some embodiments, the wiring harness electrically connects the female outlet, the indicator light, the optional activation switch, and the power adapter or interior power source together into a circuit adapted to measure the continuity of the heater. Some versions allow for remote use of the tester or provide the tester in kit form.

A method of using a block heater test system is also disclosed comprising the steps of installing battery into the block heater test assembly, connecting to a vehicle block heater plug, pressing the test button to test the vehicle block heater, viewing the indicator light to read the test result, and disconnecting the block heater test assembly. The method may further comprise the step of listening to a test tone.

The present invention holds significant improvements and serves as a block heater test system. For purposes of summarizing the invention, certain aspects, advantages, and novel features of the invention have been described herein. It is to be understood that not necessarily all such advantages may be achieved in accordance with any one particular embodiment of the invention. Thus, the invention may be embodied or carried out in a manner that achieves or optimizes one advantage or group of advantages as taught herein without necessarily achieving other advantages as may be taught or suggested herein. The features of the invention which are believed to be novel are particularly pointed out and distinctly claimed in the concluding portion of the specification. These and other features, aspects, and advantages of the present invention will become better understood with reference to the following drawings and detailed description.

### BRIEF DESCRIPTION OF THE DRAWINGS

The figures that accompany the written portion of this specification illustrate embodiments and method(s) of use for the present invention, block heater test system, constructed and operative according to the teachings of the present invention.

FIG. 1 shows a perspective view illustrating a block heater test system during an ‘in-use’ condition showing a user testing a block heater according to an embodiment of the present invention.

FIG. 2 is a perspective view illustrating the block heater test system comprising a power switch, an indicator light, and a female outlet according to an embodiment of the present invention of FIG. 1.

FIG. 3 is a perspective view illustrating various components of the block heater test system according to an embodiment of the present invention of FIGS. 1-2.

FIG. 4 is a perspective view illustrating the block heater test system according to an embodiment of the present invention of FIGS. 1-3.

FIG. 5 is a flowchart illustrating a method of use for the block heater test system according to an embodiment of the present invention of FIGS. 1-4.

FIG. 6 is a schematic of an electrical circuit of an invention embodiment.

The various embodiments of the present invention will hereinafter be described in conjunction with the appended drawings, wherein like designations denote like elements.

### DETAILED DESCRIPTION

As discussed above, embodiments of the present invention relate to automotive testing devices and more particularly to a block heater test system as used to improve the testing of continuity in a vehicle's block heater.

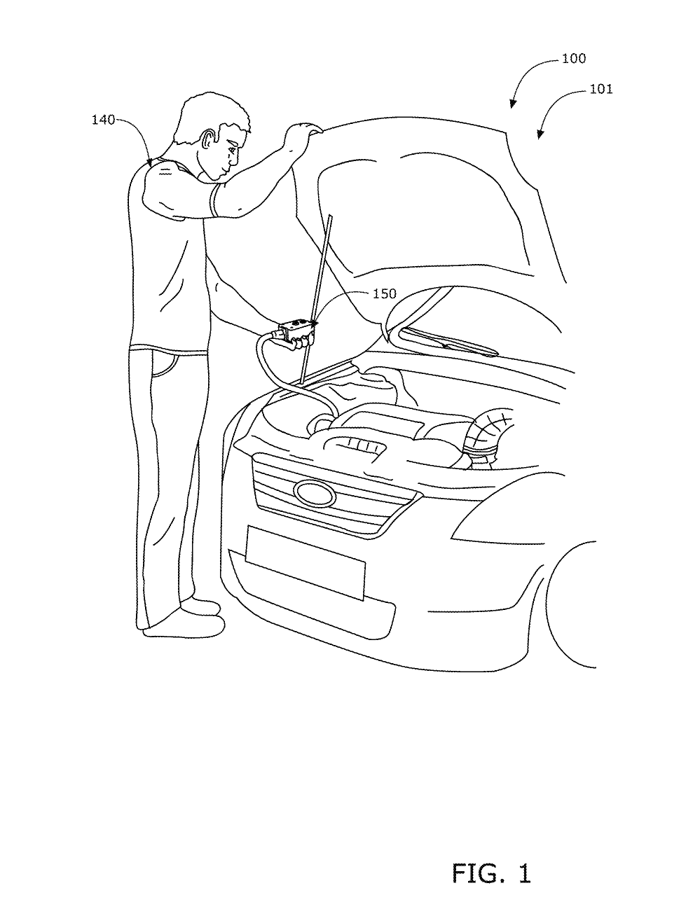

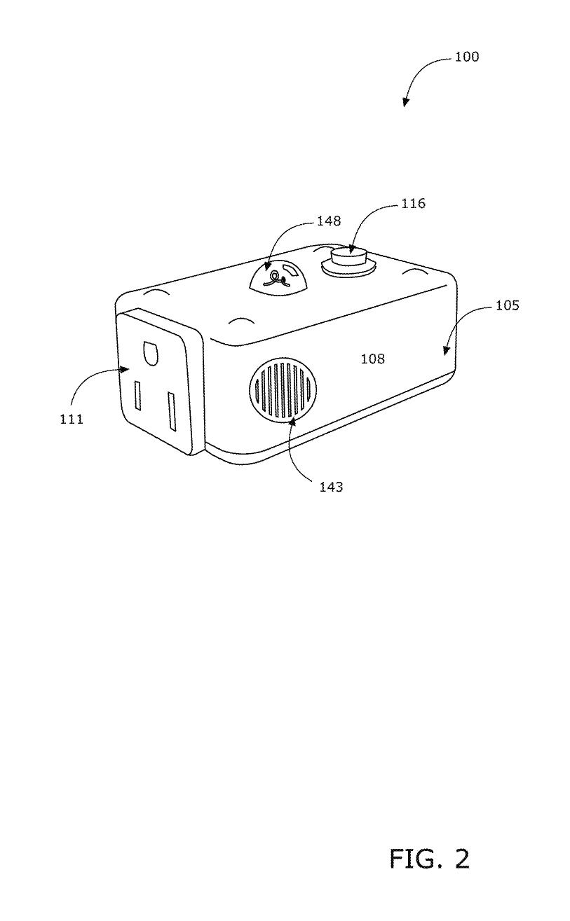

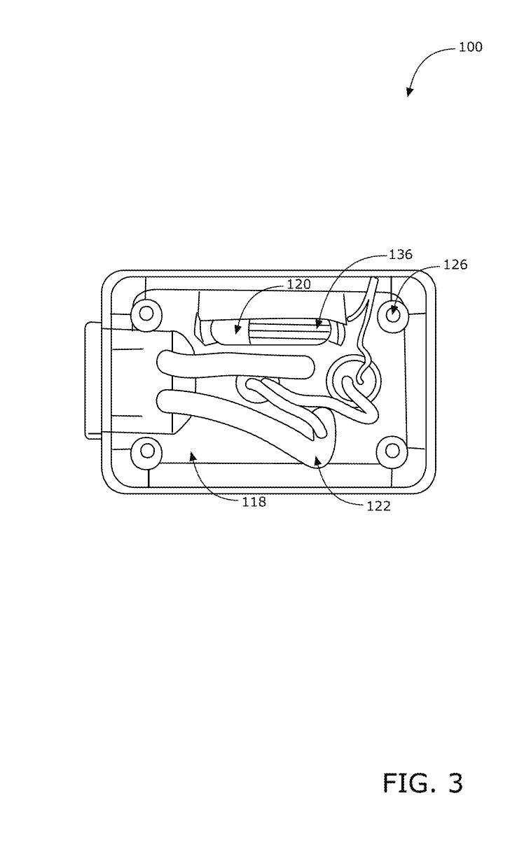

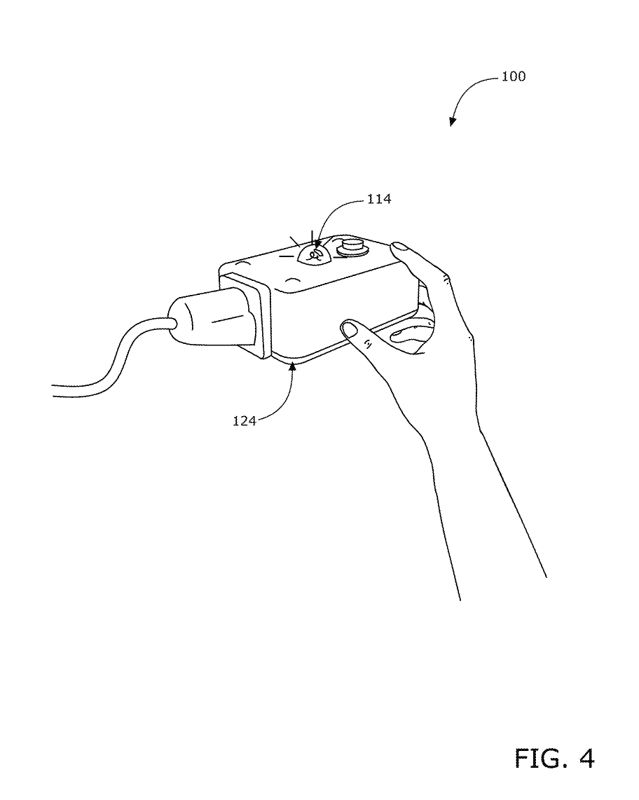

Referring to the drawings by numerals of reference there is shown in FIGS. 1-4 block heater test system 100 comprising block heater test assembly 101. Block heater test assembly 101 comprises housing 105, inner volume 118, and rear cover 124. Housing 105 comprises outer surface 108, female outlet 111, at least one indicator light 114, and, in some embodiments, activation switch 116. Inner volume 118 comprises internal power source 120 and wiring harness 122. Rear cover 124 comprising aperture 126. Female outlet 111 receives male power-supply plug of block heater 71. Outer surface 108 mounts female outlet 111, indicator light 114, and, optionally, activation switch 116 in test assembly 101. In some embodiments, activation switch 116 is used for activation of block heater test assembly 101. In other embodiments, inserting plug 71 into female outlet 111 activates block heater test assembly 101. Internal power source 120 powers block heater test assembly 101. Wiring harness 122 transfers the power to female outlet 111, indicator light 114, and activation switch 116, in embodiments with this switch. Rear cover 124 connects to housing 105.

As discussed above, block heater test assembly 101 contains female outlet or receptacle 111, activation switch 116 (optional), and indicator light 114, mounted inside of housing 105. The female outlet or receptacle 111 facilitates, through at least two terminals 1011 and 1012, connection to a heater in thermal contact with an engine block or the coolant in an engine block—a block heater. Such heaters typically use a plug to connect the heater to electrical power by plugging into a power receptacle. Examples of useful receptacles and plugs include those plugs that follow the NEMA 5 standard.

Block heater test assembly 101 uses internal or external power source 120, depending on the embodiment. Useful internal power sources 1051 include battery or supercapacitors. Some embodiments use external power source 1052. In some of these embodiments, block heater test assembly 101 additionally comprises a power-in port 1060, which can be any of the standard power plugs well-known in the art.

In embodiments with internal power source 1051 (or with both internal power source 1051 and external power source 1052), terminal 1011 electrically connects to one side of internal power source 1051 directly, through activation switch 116, through indicator light 114, or through both activation switch 116 and indicator light 114. Terminal 1012 electrically connects to the other side of power source 1051 directly, through activation switch 116, through indicator light 114 or through both activation switch 116 and indicator light 114. In some embodiments, terminal 1011 and terminal 1012 both electrically connect to internal power source 1051 through activation switch 116. One or the other of terminals 1011 and 1012 connect to internal power source 1051 through indicator light 114. In some embodiments, one of terminal 1011 and terminal 1012 connects to internal power source 1051.

In some embodiments with external power source 1052 (or embodiments with both external power source 1052 and internal power source 1051), terminal 1011 electrically connects to one side of external power source 1052 directly, through activation switch 116, through indicator light 114, or through both activation switch 116 and indicator light 114. Terminal 1012 electrically connects to the other side of external power source 120 directly, through activation switch 116, through indicator light 114 or through both activation switch 116 and through indicator light 114. In some embodiments, terminal 1011 and terminal 1012 both electrically connect to external power source 1052 through activation switch 116. One or the other of terminals 1011 and 1012 connects to external power source 1052 through indicator light 114. In some embodiments, one of terminal 1011 and terminal 1012 connects to external power source 1052. In some embodiments, the electrical connections are made through wiring harness 122.

Block heater test system 100 is structured and arranged for testing block heater 71 of a vehicle. In some embodiments, block heater test assembly 101 may comprise speaker 143 and speaker volume control (not shown) to indicated continuity when testing. In some embodiments, outer surface 108 may comprise plastic to provide a non-conductive shell to insulate a user from electrical current. Female outlet 111 may comprise a 3-prong design. Internal power source 120 may be battery 136. This vehicle contains heater 71 in some embodiments and in other embodiments heater 71 is in another vehicle or a freestanding engine. Indicator light 114 comprises at least one light emitting diode 148. In these or other embodiments, outer surface 108 comprises a whether resistant coating.

Inner volume 118 comprises a waterproof seal to prevent water from entering inner volume 118 through any gap that may be between the rear cover 128 and housing 105. Inner volume 118 comprises a vibration oscillator. Rear cover 128 comprises an attachment apertures 126. Attachment apertures 126 comprise clips. Block heater test assembly 101 is able to be remotely used.

Block heater test system 100 may be sold as kit 440 comprising the following parts: at least one block heater test assembly 101; at least one set of battery 136; and at least one set of user instructions. The kit has instructions such that functional relationships are detailed in relation to the structure of the invention (such that the invention can be used, maintained, or the like in a preferred manner). Block heater test system 100, tester 101, or block heater test assembly 101 may be manufactured and provided for sale in a wide variety of sizes and shapes for a wide assortment of applications. Upon reading this specification, it should be appreciated that, under appropriate circumstances, considering such issues as design preference, user preferences, marketing preferences, cost, structural requirements, available materials, technological advances, etc., other kit contents or arrangements such as, for example, including more or less components, customized parts, different powering combinations, parts may be sold separately, etc., may be sufficient.

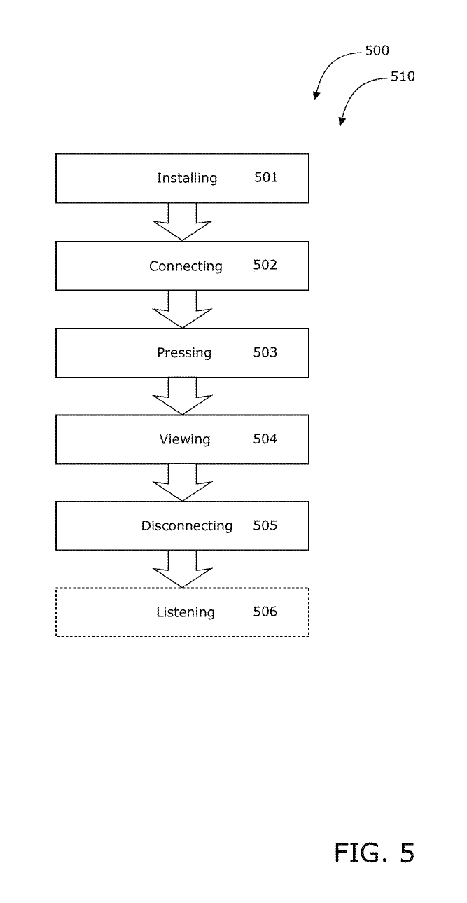

FIG. 5 shows flowchart 550 illustrating method of use 500 for block heater test system 100 according to an embodiment of the present invention. As shown, method of use 500 may comprise the steps of: installing battery 136 into block heater test assembly 501, connecting to a vehicle block heater plug 502, pressing the test button or activation switch 116 to test the vehicle block heater 503, viewing the indicator light to read the test result 504, and disconnecting block heater test assembly 505. Optional steps of method of use 500 are illustrated using dotted lines in FIG. 5 so as to distinguish them from the other steps of method of use 500.

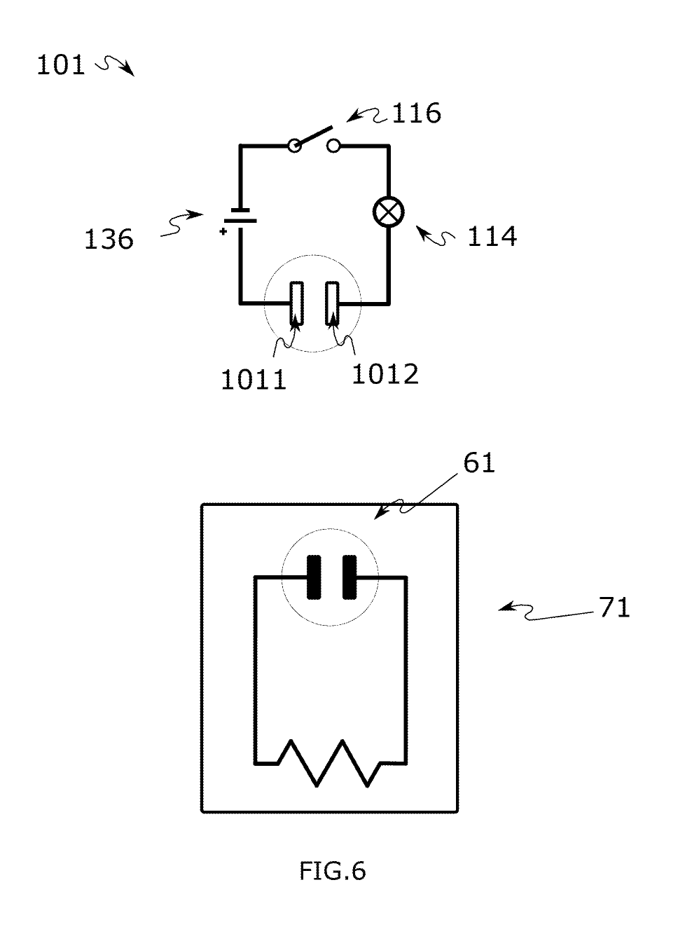

FIG. 6 illustrates a circuit diagram of block heater test assembly or tester 101. This diagram represents the internal power source as battery 136. In this embodiment, battery 136 has a positive terminal and a negative terminal. The negative terminal connects to a first terminal of activation switch 116. The positive terminal connects to a first terminal 1011 of a female configured plug. A second terminal of activation switch 116 connects to a first terminal of indicator light 114. A second terminal of indicator light 114 connects to the second terminal 1012 of the female configured plug.

Prior art block heater 71 contains male configured plug 61 and is a resistance-type heater, represented by the resistor symbol in FIG. 6.

When in a testing configuration, plug 61 is connected into the receptacle containing first terminal 1011 and second terminal 1012. This connection results in electrical contact between the terminals of plug 61 and first and second terminals 1011 and 1012. This connection completes the circuit of tester 101, if block heater 71 is operational. Thus, an operational block heater 71 allows current to flow through the circuit when activation switch 116 is closed. When current flows, indicator light 114 illuminates.

In operation, block heater test assembly 101 when internally powered, connects to block heater 71 by receiving the heater's plug into female outlet or receptacle 111. The operator manipulates activation switch 116 to close it. Closing activation switch 116 allows electrical current to flow through activation switch 116 and light 114, causing light 114 to illuminate IF the heater itself has a continuous electrical path. That is, if the circuit through block heater 71 is continuous, indicator light 114 lights when activation switch 116 is closed.

For embodiments without activation switch 116, when the operational block heater is connected to outlet 1010, the block heater completes the circuit and indicator light 114 lights.

Straightforward modification of the circuit allows for indicator light 1031 indicating the device is powered on and for indicator light 114 to indicate circuit completion through block heater. Alternatively, the circuit can be modified so that indicator light 114 illuminates when a fault exists in block heater 71.

It should be noted that the steps described in the method of use can be carried out in many different orders according to user preference. The use of “step of” should not be interpreted as “step for”, in the claims herein and is not intended to invoke the provisions of 35 U.S.C. § 112, ¶6. Upon reading this specification, it should be appreciated that, under appropriate circumstances, considering such issues as design preference, user preferences, marketing preferences, cost, structural requirements, available materials, technological advances, etc., other methods of use arrangements such as, for example, different orders within above-mentioned list, elimination or addition of certain steps, including or excluding certain maintenance steps, etc., may be sufficient.

The embodiments of the invention described herein are exemplary and numerous modifications, variations and rearrangements can be readily envisioned to achieve substantially equivalent results, all of which are intended to be embraced within the spirit and scope of the invention. Further, the purpose of the foregoing abstract is to enable the U.S. Patent and Trademark Office and the public generally, and especially the scientist, engineers and practitioners in the art who are not familiar with patent or legal terms or phraseology, to determine quickly from a cursory inspection the nature and essence of the technical disclosure of the application.

What is claimed is new and desired to be protected by Letters Patent is set forth in the appended claims:

1. A tester comprising:
a housing having:
a power adapter or an interior power source;
an outer surface with a female outlet, indicator light, and an optional activation switch;
and
an interior with a wiring harness,
wherein
the female outlet is structured and arranged to receive a male power plug connected to an engine-block heater
and
the wiring harness electrically connects the female outlet, the indicator light, the optional activation switch, and the power adapter or interior power source together into a circuit adapted to indicate the continuity of the heater.

2. The tester of claim 1 having:
testing states that include an energized configuration and a non-energized configuration;
and
standby states that include an energized configuration and a non-energized configuration,
wherein in the testing states a heater is connected to the outlet,
wherein in the standby states a heater is not connected to the outlet,
wherein in an energized configuration the circuit supplies a voltage across the outlet,
and
wherein in a non-energized state the circuit does not supply a voltage across the outlet.

3. The tester of claim 2 wherein the heater comprises a continuous electrical path, the tester is in the testing state and the energized configuration, and the indicator light illuminates.

4. The tester of claim 3 wherein the heater test assembly is able to be used remotely.

5. The tester of claim 4 wherein the internal power source comprises a battery.

6. The tester of claim 5 wherein the optional activation switch is present and has an open position corresponding to the non-energized state and a closed position corresponding to the energized state.

7. The tester of claim 6 wherein the indicator light comprises at least one light emitting diode.

8. The tester of claim 7 wherein the battery is rechargeable.

9. The tester of claim 3 wherein the power adapter receives power from outside the tester.

10. The tester of claim 9 wherein the optional activation switch is present and has an open position corresponding to the non-energized state and a closed position corresponding to the energized state.

11. The tester of claim 10 wherein the indicator light comprises at least one light emitting diode.

12. The tester of claim 11 wherein the heater test assembly is able to be used remotely.

13. The tester of claim 4 wherein the female outlet comprises an NEMA 5 compliant receptacle.

14. The tester of claim 1 wherein the heater test assembly is able to be remotely used.

15. A tester comprising:
a housing having:
a power adapter or an interior power source;
an outer surface with a female outlet, indicator light, and an optional activation switch;
and
an interior with a wiring harness;
and
a rear cover comprising an attachment aperture,
and having:
testing states that include an energized configuration and a non-energized configuration;
and
standby states that include an energized configuration and a non-energized configuration,
wherein
in the testing states a heater is connected to the outlet,
in the standby states a heater is not connected to the outlet,
in an energized configuration the circuit supplies a voltage across the outlet,
and
in a non-energized state the circuit does not supply a voltage across the outlet
wherein
the heater comprises a continuous electrical path, the tester is in the testing state, and the energized configuration and the indicator light illuminates
the internal power source comprises a battery,
the wiring harness electrically connects the female outlet, the indicator light, the optional activation switch, and the power adapter or interior power source together into a circuit adapted to measure the continuity of the heater
the indicator light comprises at least one light emitting diode,
the interior comprises the power source used for powering the block heater test assembly,
the power source comprises battery and an adapter for an external power source,
and
the heater test assembly is able to be remotely used.

16. The tester of claim 15 further comprising a kit including the block heater test assembly, battery, and a set of user instructions.

17. A method of using a tester comprising:
installing battery into the tester of claim 1;
connecting the tester to an engine-block heater plug;
viewing the indicator light to read the test result;
and
disconnecting the tester.

18. The method of claim 17 further comprising pressing the activation switch to test the vehicle block heater.
